(19) United States
(12) Patent Application Publication
(10) Pub. No.: US 2026/0231733 A1
(43) Pub. Date: Aug. 6, 2026

(54) METHOD FOR DETECTING ABNORMALITY IN PROCESS, PROGRAM STORED IN RECORDING MEDIUM, AND SUBSTRATE PROCESSING APPARATUS

(71) Applicants: PSK Inc., Hwaseong-si (KR); RTM Inc., Seoul (KR)

(72) Inventors: Tae Kyung HA, Hwaseong-si (KR); Gyu Il HWANG, Seoul (KR); Seung Heui LEE, Seoul (KR)

(21) Appl. No.: 19/465,982

(22) Filed: Jan. 30, 2026

(30) Foreign Application Priority Data
Jan. 31, 2025 (KR) 10-2025-0012720

(51) Int. Cl. H10P 74/20; H10P 72/00

(52) U.S. Cl. CPC H10P 74/203; H10P 72/0604

(57) ABSTRACT

An exemplary embodiment of the present invention provides a method of detecting a process abnormality, the method including: deriving reference data from a plurality of sample data, and comparing the derived reference data with determination target data to detect an abnormality in a process performed while the determination target data is collected, in which the sample data and the determination target data are data collected while a process of processing a substrate is performed, the reference data includes: a first reference band, which is a threshold range at a first data point; and a second reference band, which is a threshold range at a second data point, in which the second data point is a point having a measurement value acquisition time point different from the first data point, and the first reference band and the second reference band have different sizes.

### CROSS-REFERENCE TO RELATED APPLICATION

This application claims priority to and the benefit of Korean Patent Application No. 10-2025-0012720 filed in the Korean Intellectual Property Office on Jan. 31, 2025 the entire contents of which are incorporated herein by reference.

### TECHNICAL FIELD

The present invention relates to a process abnormality detecting method, a program stored in a recording medium, and a substrate processing apparatus, and more particularly, to a process abnormality detecting method, a program stored in a recording medium, and a substrate processing apparatus that detect whether an abnormality has occurred in a processing process for a substrate based on process data collected by a sensor.

### BACKGROUND ART

In order to manufacture a semiconductor device, various processes, such as cleaning, etching, strip, deposition, passivation, ion implantation, and baking, are performed. This process is performed continuously and/or repeatedly on a substrate, such as a wafer.

With the high integration of semiconductor devices, fine line widths of the patterns formed on the substrate is required. In order to realize the fine line width of the pattern, it is necessary to appropriately detect whether an abnormality has occurred in a process of processing the substrate.

To this end, various types of sensors are attached to the chamber. The sensors collect various process data on a process environment while the substrate is processed. For example, the sensor collects various process data on a process environment in which the substrate is processed, such as temperature, pressure, voltage, and current of a space or substrate in the chamber.

In general, process abnormalities are detected by applying Stochastic Process Control (SPC) and Fault Detection and Classification (FDC) methodologies to the collected process data. These methodologies set an upper threshold value and a lower threshold value using statistical values (mean, variance, etc.) in a specific section of process data collected by the sensor, and determine that process abnormalities have occurred when process data requiring judgment exceeds the threshold value. If a process abnormality occurs, a user may be alerted through a control device provided in the semiconductor manufacturing equipment. In addition, process data in which process abnormalities have occurred is additionally analyzed.

Meanwhile, process data measured by the sensor is collected according to a predetermined measurement period (e.g., 300 ms). A point (time point) at which a measurement value is collected according to a measurement period is referred to as a data point.

In order to detect process abnormalities, a plurality of sample data, which is process data collected when a normal process is performed, are collected. In the above-described SPC or FDC methodology, measurement values for all or a part of a plurality of data points in collected sample data are statistically processed. The average, variance, and the like are derived through statistical processing, and the above-described upper limit threshold value and lower limit threshold value are set based on the derived average, variance, and the like.

However, in reality, the length of the sample data differs somewhat due to an error in the measurement time point of the sensor. For example, even if the same process recipe is performed in the chamber, the data points of the sample data may be shifted before and after different from the actual measurement time point due to the above-described error.

In addition, the process of processing one substrate includes a plurality of process steps. For example, the process includes a first process step, a second process step, and . . . , and the like. In addition, errors may occur at the start time point and the end point of the process in the process chamber. Due to this error, there may be a problem that the data point to be recorded in the first process step is recorded in the second process step. Also, the light narrowness of the measurement value distribution measured by the sensor may be different according to the process step included in the process. Therefore, when the above threshold value range is set equally without considering the process step, there may be a case in which determination target data of the normal process is determined as an abnormal process or determination target data of the abnormal process is determined as a normal process.

### SUMMARY OF THE INVENTION

The present invention has been made in an effort to provide a process abnormality detecting method, a program stored in a recording medium, and a substrate processing apparatus that are capable of effectively detecting process abnormality.

The present invention has been made in an effort to provide a process abnormality detecting method, a program stored in a recording medium, and a substrate processing apparatus that derive precise reference data, even though sample data having different data lengths or shifted before and after based on an actual data point is used.

The present invention has been made in an effort to provide a process abnormality detecting method, a program stored in a recording medium, and a substrate processing apparatus that improve the precision of process abnormality detection by setting a size of a reference band differently depending on a process time point in reference data.

The problem to be solved by the present invention is not limited to the above-mentioned problems, and the problems not mentioned will be clearly understood by those skilled in the art from the present specification and the accompanying drawings.

An exemplary embodiment of the present invention provides a method of detecting a process abnormality, the method including: deriving reference data from a plurality of sample data, and comparing the derived reference data with determination target data to detect an abnormality in a process performed while the determination target data is collected, in which the sample data and the determination target data are data collected while a process of processing a substrate is performed, the reference data includes: a first reference band, which is a threshold range at a first data point; and a second reference band, which is a threshold range at a second data point, in which the second data point is a point having a measurement value acquisition time point different from the first data point, and the first reference band and the second reference band have different sizes.

According to the exemplary embodiment, the deriving of the reference data may include: selecting sample data having the longest data length among the plurality of sample data as representative sample data, and mapping the selected representative sample data and each of general sample data excluding the representative sample data among the plurality of sample data.

According to the exemplary embodiment, in the deriving of the reference data, when the representative sample data and each of the general sample data are mapped, a cost table of the representative sample data and the general sample data may be calculated by applying a dynamic time warping algorithm, and the mapping may be performed based on data points that serve as a minimum cost path in the cost table, and the mapping may be performed based on the data points of the representative sample data.

According to the exemplary embodiment, in the deriving of the reference data, after performing the mapping, a distribution of the measurement values may be calculated for each of the data points.

According to the exemplary embodiment, in the deriving of the reference data, the reference data may be derived by removing data having a value equal to or greater than a maximum setting value and equal to or less than to a minimum setting value from the distribution of each of the data points.

According to the exemplary embodiment, in the process of processing the substrate, different types of sensors each collect the sample data and the determination target data, first reference data, which is the reference data, may be derived from the sample data collected by a first sensor, second reference data, which is the reference data, may be derived from the sample data collected by a second sensor of a different type from the first sensor, and based on a result of comparing first determination target data, which is the determination target data, collected by the first sensor with the first reference data, and a result of comparing second determination target data, which is the determination target data, collected by the second sensor with the second reference data, it is determined whether the process of processing the substrate is abnormal.

In addition, an exemplary embodiment of the present invention provides a non-transitory computer-readable recording medium storing a program comprising instructions which, when executed by a processor, cause the processor to perform the method of detecting the process abnormality.

In addition, the present invention provides an apparatus for processing a substrate. the apparatus comprising: a process chamber for performing a process of processing the substrate; at least one sensor for collecting a measurement value for a process factor related to the process; and a controller for receiving the measurement value measured by the sensor, wherein the controller controls the process chamber to perform the process of processing the substrate multiple times to collect a plurality of sample data from the sensor, and derives reference data from the plurality of sample data and stores the derived reference data in a recording medium of the controller, the reference data includes: a first reference band, which is a threshold range at a first data point; and a second reference band, which is a threshold range at a second data point, in which the second data point is a point having a measurement value acquisition time point different from the first data point, and the first reference band and the second reference band may have different sizes.

According to the exemplary embodiment, in the deriving of the reference data, the controller may select sample data having the longest data length among the plurality of sample data as representative sample data, and may map the selected representative sample data and each of general sample data excluding the representative sample data among the plurality of sample data.

According to the exemplary embodiment, in the deriving of the reference data, when the representative sample data and each of the general sample data are mapped, the controller calculates a cost table of the representative sample data and the general sample data by applying a dynamic time warping algorithm, and performs the mapping based on data points that serve as a minimum cost path in the cost table, and the mapping may be performed based on the data points of the representative sample data.

According to the exemplary embodiment, in the deriving of the reference data, the controller may calculate a distribution of the measurement values for each of the data points, after performing the mapping.

According to the exemplary embodiment, in the deriving of the reference data, the controller may derive the reference data by removing data having a value equal to or greater than a maximum setting value and equal to or less than to a minimum setting value from the distribution of each of the data points.

According to the exemplary embodiment, further comprising: a plurality of different types of the sensors, wherein each of the sensors collects the sample data and determination target data that requires determination of whether a process abnormality has occurred and transmits the measurement value to the controller, and the controller derives first reference data, which is the reference data, from the sample data collected by a first sensor among the sensors, derives second reference data, which is the reference data, from the sample data collected by a second sensor of a different type from the first sensor among the sensors, and determines whether the process of processing the substrate is abnormal based on a result of comparing first determination target data, which is the determination target data, collected by the first sensor with the first reference data, and a result of comparing second determination target data, which is the determination target data, collected by the second sensor with the second reference data.

According to the exemplary embodiment of the present invention, it is possible to effectively detect process abnormality.

Further, according to the exemplary embodiment of the present invention, it is possible to derive precise reference data, even though sample data having different data lengths or shifted before and after based on an actual data point is used.

Further, according to the exemplary embodiment of the present invention, it is possible to improve the precision of process abnormality detection by setting a size of a reference band differently depending on a process time point in reference data.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

FIG. 1 is a diagram schematically illustrating a substrate processing apparatus according to an exemplary embodiment of the present invention.

FIG. 2 is a flowchart illustrating a process abnormality detecting method according to an exemplary embodiment of the present invention.

FIG. 3 is a block diagram for describing sample data used for deriving reference data.

FIGS. 4 and 5 are graphs illustrating a state in which representative sample data and general sample data are mapped among the sample data of FIG. 3.

FIGS. 6 and 7 are data for describing a method of mapping representative sample data and general sample data by applying a Dynamic Time Warping (DTW) algorithm.

FIG. 8 is a graph for describing a method for deriving reference data including a reference band by applying an Inter Quartile Range (IQR) to each data point.

FIG. 9 is a graph illustrating reference data for determining whether a process at the time of collecting determination target data is an abnormal process.

FIG. 10 is a graph for describing a method of determining whether a process at the time of collecting determination target data is an abnormal process by applying the reference data of FIG. 9.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Exemplary embodiments will now be described more fully with reference to the accompanying drawings. The exemplary embodiments are provided in order to make the disclosure exhaustive and will fully convey the scope to one of ordinary skill in the art. To provide a complete understanding of exemplary embodiments of the present invention, a number of specific details are presented, such as examples of certain components, devices, and methods. It will be apparent to those skilled in the art that specific details need not be utilized and that the exemplary embodiments may be implemented in many different forms, neither of which should be construed as limiting the scope of the present invention. In some exemplary embodiments, known processes, known device structures, and known techniques are not described in detail.

The terminology used herein is intended to describe certain exemplary embodiments only and is not intended to limit the exemplary embodiments. Singular expressions, such as those used herein, or expressions where the singular is not specified, are intended to include the plural expressions unless the context clearly indicates otherwise. The terms “includes”, “comprising”, “including”, and “having” have an open-ended meaning and are therefore intended to specify the presence of the features, configurations, integers, steps, operations, elements, and/or components mentioned and do not exclude the presence or addition of one or more other features, configurations, steps, operations, elements, components, and/or groups thereof. The method steps, processes, and operations described herein are not to be construed as necessarily being performed in the particular order in which they are discussed or described, unless the order in which they are performed is specified. In addition, additional or alternative steps may be selected.

When an element or layer is referred to as being “on”, “connected to”, “bonded to”, “attached to”, “adjacent to”, or “covering” another element or layer, the element or layer may be directly on, connected to, bonded to, attached to, adjacent to, or covering the other element or layer, or intermediate elements or layers may be present. Conversely, when an element is referred to as being “directly on”, “directly connected to”, or “directly bonded to” another element or layer, it is to be understood that no intervening elements or layers are present. Throughout the specification, the same reference numeral refers to the same element. As used in the present invention, the term “and/or” includes all combinations and sub-combinations of one or more of the enumerated items.

Although terms, such as first, second, and third, may be used to describe various elements, regions, layers, and/or sections of the present invention, it is to be understood that these elements, regions, layers, and/or sections are not to be limited by these terms. These terms are used to distinguish one element, region, layer, or section from another element, region, layer, or section only. Accordingly, the first element, first region, first floor, or first section discussed below may be referred to as the second element, second region, second floor, or second section without departing from the teachings of the exemplary embodiments.

Spatially relative terms (for example, “beneath”, “underneath”, “below”, “on”, “above”, and “on top”) may be used for ease of description to describe the relationship of one element or feature to another element(s) or feature(s) as illustrated in the drawings. It is to be understood that spatially relative terms are intended to include not only the orientations illustrated in the drawings, but also other orientations of the apparatus in use or operation. For example, when the device in the drawing is flipped, the elements described as “underneath” or “below” other elements or features may be oriented “above” other elements or features. Thus, the term “below” above may include both up and down orientations. The apparatus may be oriented differently (rotated 90 degrees, or otherwise oriented), and the spatially relative descriptive phrases used in the present invention may be construed accordingly.

It should be understood that when the terms “same” or “equal” are used in the description of exemplary embodiments, some imprecision may exist. Accordingly, when an element or value is referred to as being equal to another element or value, it is to be understood that the corresponding element or value is equal to the other element or value within manufacturing or operating tolerances (e.g., ±10%).

Where the words “approximately” or “substantially” are used in the present specification with respect to a numerical value, the corresponding numerical value should be understood to include manufacturing or operating tolerances (e.g., ±10%) of the mentioned numerical value. It should also be understood that the use of the words “generally” and “substantially” in reference to geometric shapes does not require geometric shape accuracy, but latitude for shape is within the scope of the disclosure.

Unless otherwise defined, all terms used in the present invention, including technical and scientific terms, have the same meaning as commonly understood by one of ordinary skill in the art to which the exemplary embodiments belong. It is also to be understood that terms, including commonly used dictionary-defined terms, are to be interpreted to have a meaning consistent with their meaning in the context of the relevant art and are not to be construed in an idealized or overly formal sense unless expressly defined in the present invention.

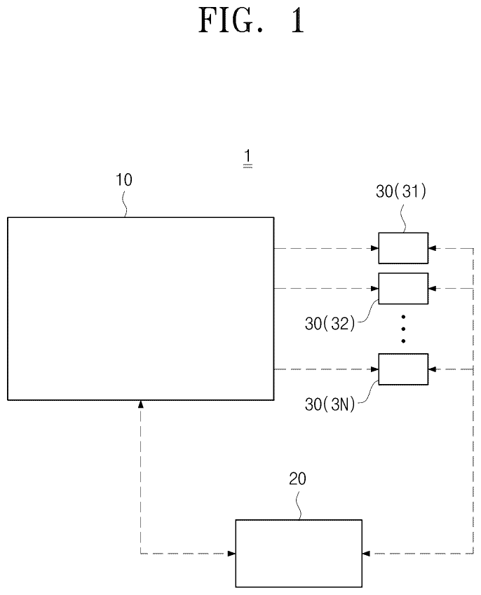

FIG. 1 is a diagram schematically illustrating a substrate processing apparatus according to an exemplary embodiment of the present invention.

Referring to FIG. 1, a substrate processing apparatus 1 according to an exemplary embodiment of the present invention may include a process chamber 10, a controller 20, and a sensor 30.

In the process chamber 10, a processing process of processing a substrate, such as a wafer, is performed. The process chamber 10 includes various process units for processing a substrate. Each process unit is configured according to the characteristics of the process to be performed.

For example, when the process chamber 10 performs an etching process or a strip process, the process chamber 10 may include a lower electrode and an upper electrode. The lower electrode supports the substrate and activates plasma by connecting a high frequency power source. The upper electrode faces the lower electrode to form an electric field, and ensures uniformity of plasma.

In some cases, a coil or antenna connected to an RF power source may be used to generate plasma. In particular, an Inductively Coupled Plasma (ICP) method induces plasma by flowing a high-frequency current through a coil. A gas supply unit for supplying reactive gas to form plasma may be included. The gas supply unit uniformly injects reactive gas, such as SF₆, CF₄, and Cl₂, into the chamber. An exhaust unit is included to remove by-products generated during the process and to keep the inside of the chamber in a vacuum state. The exhaust unit is connected to the vacuum pump to precisely control the pressure in the chamber. In addition, a temperature control unit is included to keep the temperature of the substrate constant during the process. The temperature control unit stably adjusts the temperature of the substrate surface through a cooling device or a heater.

When the process chamber 10 performs a deposition process, the process chamber 10 is provided with a deposition unit for uniformly forming a thin film. In a Chemical Vapor Deposition (CVD) method, a unit for supplying reactive gas to the surface of the substrate and removing by-products may be included. In a Physical Vapor Deposition (PVD) method, a sputtering source, a target material, and a magnetic field that adjusts a magnetic field are included.

The process chamber 10 may include various process units. An ion source and an ion beam acceleration unit may be included to perform an ion implantation process. A heating unit may be disposed to perform the baking process. A liquid injection unit and a discharge unit may be included for the cleaning process. The respective process units are designed in combination to implement a specific process recipe.

The controller 20 is a computing device for controlling the process chamber 10, and performs control required for process performance and process abnormality detection. The controller 20 stores a process recipe for controlling the process chamber 10 and reference data SD for detecting process abnormality in advance.

The process recipe includes control conditions over time of various process units provided to the process chamber 10 for execution of the substrate processing process. For example, the process recipe may include the type and supply amount of gas of the gas supply unit set for each process step, the electrode voltage of the plasma unit and the frequency of the RF power, the heating or cooling conditions of the temperature control unit for maintaining the temperature inside the chamber, and the like.

In addition, reference data SD derived in advance for process abnormality detection is stored in the recording medium of the controller 20. The reference data SD defines a normal range of process data, and based on the normal range, it is possible to determine whether the process is abnormal by comparing the normal range with determination target data TD, which is process data collected in real time or collected in advance. The reference data SD is calculated from a plurality of sample data SDN including representative sample data RD. The reference data SD includes a threshold range (reference band) for each data point.

The controller 20 includes a processor, a recording medium, a display device, such as a display, and an input device, such as a keyboard, to perform this function. The processor controls each process unit of the process chamber 10 according to the process recipe, and analyzes the data collected from the sensor 30 in real time to determine whether the process is abnormal. The recording medium stores data, such as a process recipe, reference data SD, determination target data TD, which is process data collected while performing a process, and process abnormality detection result. In addition, a program implementing a process abnormality detecting method described below may be stored on the recording medium. The corresponding program is implemented by a processor.

The display device supports a user to easily check by displaying the current state of the process, the result of the process abnormality detection, details of the process recipe, and the like. The display device visually provides information through a Graphic User Interface (GUI) and may output a graph of process data or an abnormality warning message. An input device, such as a keyboard or a touch screen, allows a user to set or modify a process recipe and input a measure according to the result of the process abnormality detection.

In addition, the controller 20 may be designed to include a network communication module to connect with an external database or to remotely control a process. Through this configuration, the controller 20 guarantees stable and precise control of the process chamber 10 and may perform advanced functions, such as process abnormality detection.

The sensor 30 is installed inside or outside the process chamber 10 and measures various process factors related to the process while the processing process is performed on the substrate. Here, the process factors include data related to a process environment for processing a substrate, such as a temperature, a pressure, and a temperature of a substrate inside the process chamber 10. A plurality of sensors 30 may be provided. The plurality of sensors 30 includes a first sensor 31, a second sensor 32, . . . , and an N^{th} sensor 3N. Each of the sensors 30 may be provided indifferent types.

The type of sensor 30 may be variously configured according to the characteristics and process conditions of the process chamber 10. For example, the sensor 30 may be provided in various types, such as a temperature sensor, a pressure sensor, a plasma sensor, a gas sensor, a current and a voltage sensor, a humidity sensor, a particle sensor, a vibration sensor, and an optical sensor.

The temperature sensor measures the temperature inside the chamber and the temperature of the substrate surface. The sensor may be generally implemented in the form of a thermocouple or an infrared thermometer. The pressure sensor may monitor the atmospheric pressure state inside the chamber. The plasma sensor measures the density and uniformity of plasma during an etching or deposition process. An Optical Emission Spectrometer (OES) that analyzes light generated during plasma discharge or a Langmuir probe that measures the electron density in the plasma may be used. The gas sensor measures the concentration and flow rate of reactive gas supplied into the chamber. A Mass Flow Controller (MFC) or an infrared absorption spectrum device that analyzes the concentration of specific gas may correspond to the gas sensor. The current and voltage sensor may measure the current and voltage flowing through an electrode used during the process. The humidity sensor may detect the moisture content of the process environment. The particle sensor may detect the presence of fine particles generated during the process or introduced from the outside.

In addition, a vibration sensor that detects the vibration of the chamber during the process, an optical sensor that analyzes the surface state of the substrate in real time, and the like may be additionally included. These sensors may accurately monitor each process condition and environment.

Hereinafter, a process abnormality detecting method according to an exemplary embodiment of the present invention will be described in detail. The process abnormality detecting method according to the exemplary embodiment of the present invention includes deriving reference data SD, collecting determination target data TD requiring determination on whether a process abnormality has occurred, and detecting process abnormality by comparing the reference data SD and the determination target data TD with each other. Hereinafter, a specific method thereof will be described in detail.

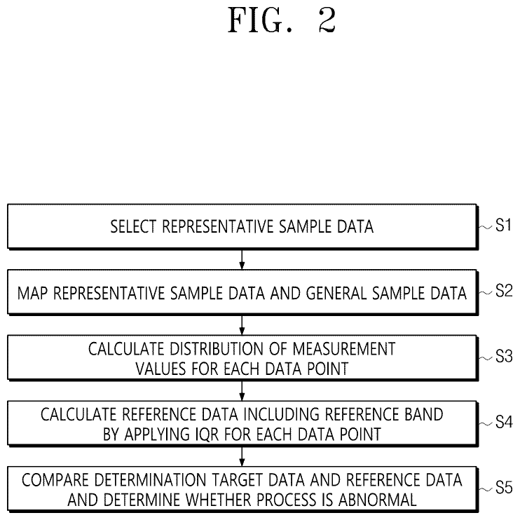

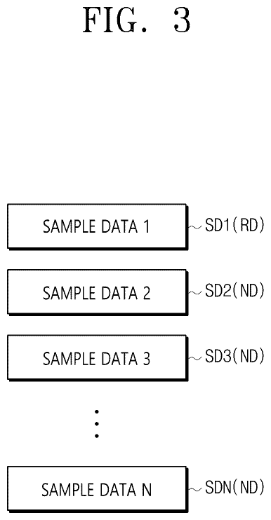

FIG. 2 is a flowchart illustrating a process abnormality detecting method according to an exemplary embodiment of the present invention, and FIG. 3 is a block diagram for describing sample data SDN used for deriving reference data SD.

Referring to FIGS. 2 and 3, in operation S1, representative sample data RD is selected. In order to select the representative sample data RD, a plurality of sample data SDN (N is a natural number) is collected. For example, sample data 1 SD1, sample data 2 SD2, sample data 3 SD3 . . . , and the like may be collected. The sample data SDN may be data collected when a processing process for a substrate is normally performed. Each sample data SDN may be data collected by the sensor 30 until a process starts and is terminated for one substrate. For example, sample data 1 SD1 may be data collected while processing the first substrate, and sample data 2 SD2 may be data collected while processing the second substrate. Each process may include a plurality of process steps. A process step performed at a first time may be defined as a first process step, and a process step performed at a second time later than the first time may be defined as a second process step, and the like. In each process step, operating conditions of the process units provided to the process chamber 10 may be different.

The sensor 30 collects process data according to a predetermined measurement period. For example, the measurement period may be 300 ms. Each time point at which a measurement value is collected according to a measurement period is referred to as a data point. The sample data SDN include measurement values of the sensor 30 for a plurality of data points. Accordingly, the sample data SDN includes a measurement value measured by the sensor 30 while the processing process is performed on the substrate and information on a change of the measurement value over time.

Ideally, the number of data points included in the sample data SDN need to be all the same. However, since some errors may occur at the start time point and the end point of the process in the process chamber 10, the number of data points included in each sample data SDN may be different.

Among the above-described sample data SDN, sample data including the largest number of data points (i.e., the longest data length) may be selected as the representative sample data RD. In addition, remaining sample data excluding the representative sample data may be selected as general sample data ND. When the representative sample data RD is selected, the sample data SDN having an excessively long data length is excluded from data used to derive a candidate of the representative sample data RD and the reference data SD. For example, when the length of data of the sample data SDN having the longest length shows a significant difference beyond a preset value compared to an average length value of all sample data SDN, the corresponding sample data SDN is excluded from the candidate of the representative sample data RD, and the representative sample data RD is selected from among the remaining sample data SDN. In this case, it is because there is a high probability that the process is an abnormal process when collecting the corresponding data.

As illustrated in FIG. 3, when the data length of sample data 1 SD1 is the longest, the sample data 1 SD1 is selected as the representative sample data RD, and the remaining sample data is selected as the general sample data ND.

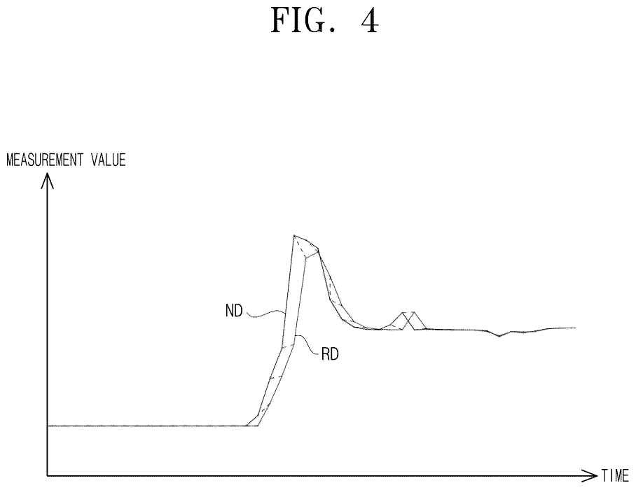

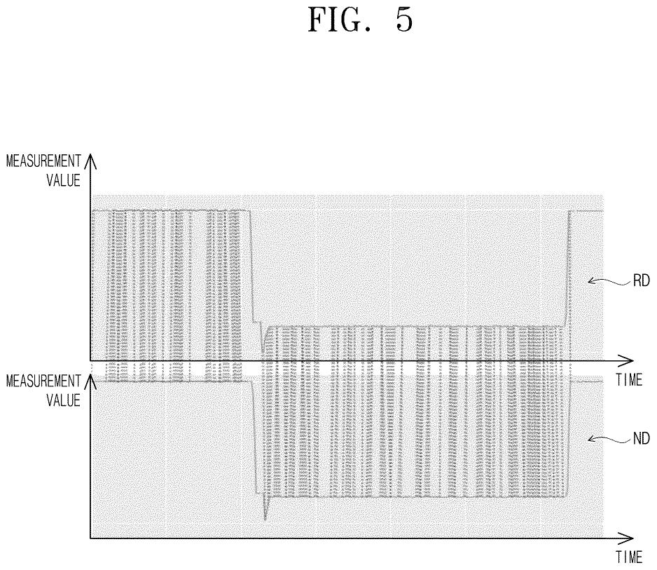

In operation S2, the representative sample data RD and the general sample data ND are mapped to each other. FIGS. 4 and 5 are graphs illustrating a state in which representative sample data and general sample data are mapped among the sample data of FIG. 3.

Referring to FIGS. 2, 4, and 5, as described above, the sample data SDN may include different numbers of data points. That is, data lengths may be different from each other. In addition, data points of the sample data SDN may be shifted before and after. Accordingly, in order to derive reference data SD that may represent a plurality of sample data SDN, alignment of the plurality of sample data SDN is necessary.

Accordingly, other general sample data ND are mapped based on the representative sample data RD. FIGS. 4 and 5 illustrate the mapping of data points of the general sample data ND based on data points of the representative sample data RD. In this case, measurement values of other general sample data ND may be checked based on the data points of the representative sample data RD.

The mapping as described above may be performed by applying a Dynamic Time Warping (DTW) algorithm. In the DTW algorithm, a cost table between the representative sample data RD and the general sample data ND is calculated, and mapping is performed by matching data points of the representative sample data RD and the general sample data ND satisfying the minimum cost path in the cost table. This mapping is performed based on the data points of the representative sample data RD. In addition, when mapping the data points of the general sample data ND based on the data points of the representative sample data RD, mapping is performed only within a range within a predetermined limit condition. For example, mapping is performed only when the time interval between the data point of the representative sample data RD and the data point of the general sample data ND is within 1 second, and mapping is not performed when the time interval exceeds 1 second. This is because when the data point of the general sample data ND is mapped based only on the similarity with the data point of the representative sample data RD, there is a possibility that an excessively far away data point in time may be drawn. When the data point is excessively far away in time, it is highly likely that the data is not suitable for data mapping. Accordingly, in the present invention, when mapping data points of the general sample data ND based on data points of the representative sample data RD, mapping is performed only within a predetermined limit condition.

Hereinafter, a method of detecting the above-described cost table and the minimum cost path will be briefly described.

FIGS. 2, 6, and 7 are data for describing a method of mapping representative sample data and general sample data by applying a Dynamic Time Warping (DTW) algorithm.

In the dynamic time warping, the dictionary meaning of warping is distortion and bending, and as its name implies, the dynamic time warping is an algorithm for “measuring the similarity (distance) between two time series with different movements depending on speed or length”, and the dynamic time warping matches the time series data in a direction that minimizes the distance to find a warping (distortion) path having the minimum cumulative distance.

The operating principle of the DTW algorithm is as follows.

It is assumed that there exist two time series Q=(q1, q2, . . . , qn), C=(C1, C2, . . . , Cn) having lengths m and n, respectively. First, two time series are listed to form an m×n matrix. The (I, j)^{th} element of this matrix means the Euclidean distance d(qi, cj)=(qi−cj)\hat{ }2 between two points qi and cj, and is used to search for an optimal warping path. The warping path W is a set of warping distances indicating the mapping between Q and C, and must be continuous.

$$W = w 1 , w 2 , … wk , max ( m , n ) \leq K < m + n - 1$$

The k^{th} element in W is defined as wk=(i,j)k, which is referred to as the warping distance. In this case, W satisfies the following three conditions.
1. Boundary conditions: w1=(1,1) and wk(m,n) should be connected. That is, the start point and the end point should be w1(1,1) and wk(m,n).
2. Continuity: In wk(a, b) and wk(a′, b′), it should be a−a′≤1, b−b′≤1. That is, the warping path is limited to adjacent cells including diagonal elements.
3. monotonicity: In wk(a,b) and wk−1=(a′, b′), it should be a−a′≥0, b−b′≥0. That is, the warping path does not move in the negative direction.

The purpose is to find a minimum cost path that minimizes the sum of the warping distances wk among the warping paths that satisfy the above three conditions. This is called a warping path cost.

$$DTW ( Q , C ) = min \{ \frac{1}{K} \sqrt{{\sum }_{k = 1}^{K} wk}$$

Here, K is used to compensate for warping paths with different lengths. The cumulative warping distance D(i,j) of the k^{th} warping distance wk starting from i=j=0 may be defined by the following equation. The meaning of the equation is [the distance between the i^{th} element and the j^{th} element]+[the minimum value of the cumulative distance to a cell adjacent to the distance of the (i,j)^{th} element], which ultimately means proceeding in the direction of the shortest distance.

The cumulative warping distance D(i,j) starts from i=j=0, and the value indicating the final similarity becomes the same as the value of DTW(Q, C) above.

$$D ( i , j ) = d ( qi , cj ) + min ( \begin{matrix}D ( i - 1 , j - 1 ) \\ D ( i - 1 , j ) \\ D ( i , j - 1 )\end{matrix} )$$

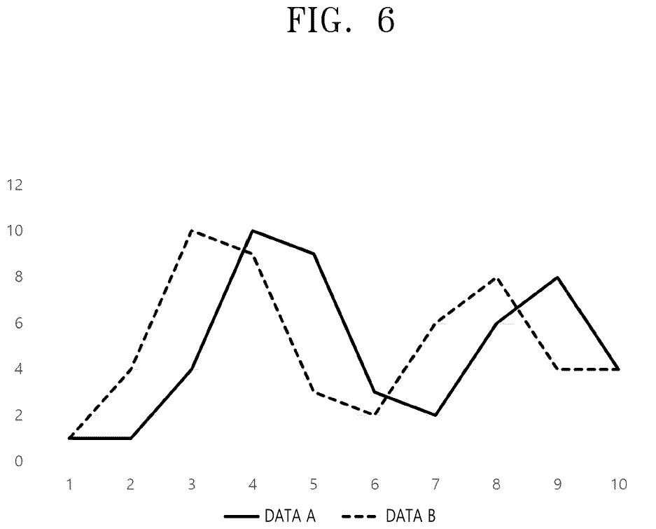

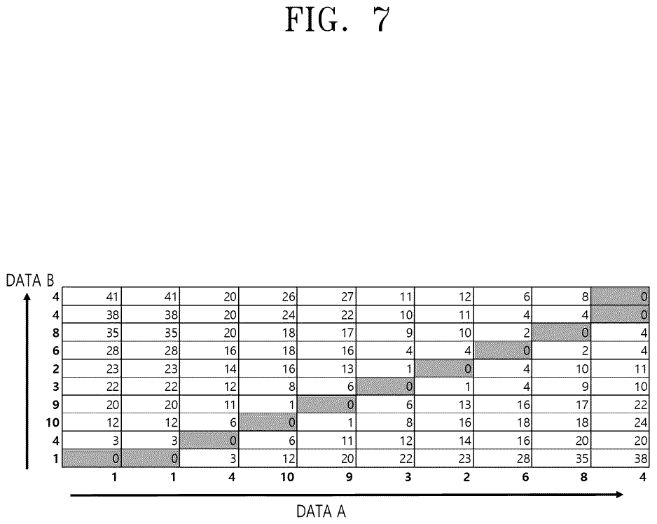

Hereinafter, a specific example will be described with reference to FIGS. 6 and 7.
1. It is assumed that there are two time series data A and data B as illustrated in Table 1 below. Data A and B may be examples of representative sample data RD and general sample data ND, respectively.

| Time | 1 | 2 | 3 | 4 | 5 | 6 | 7 | 8 | 9 | 10 |
|---|---|---|---|---|---|---|---|---|---|---|
| Data A | 1 | 1 | 4 | 10 | 9 | 3 | 2 | 6 | 8 | 4 |
| Data B | 1 | 4 | 10 | 9 | 3 | 2 | 6 | 8 | 4 | 4 |

2. Two time series are arranged to generate a 10×10 matrix as illustrated in FIG. 7. This may be referred to as a Cost Matrix.
3. The cumulative warping distance of the Cost Matrix is calculated through the following equation.

$$D ( i , j ) = d ( qi , cj ) + min ( \begin{matrix}D ( i - 1 , j - 1 ) \\ D ( i - 1 , j ) \\ D ( i , j - 1 )\end{matrix} )$$

A specific example will be given.

$$DTW ( Q , C ) = [ 0 + 0 + 0 + 0 + 0 + 0 + 0 + 0 + 0 + 0 + 0 ] / 12$$

4. In FIG. 7, the calculated Cost Matrix is displayed. The Cost Matrix may be a cost table.
5. The optimal warping path is the path with the minimum cumulative warping distance, and the search starts for the distance from the rightmost upper end point to the leftmost lower end. The search target is around the start point and becomes (4, 8, 0) around 0.
6. Among them, the minimum value of 0 is selected, and search the periphery of the selected 0.
7. The periphery of 0 is (0, 4, 4), and the minimum value of 0 is selected among them. The process proceeds to the leftmost bottom end.
8. The final path is a path shaded in FIG. 7.
9. The final selected warping path cost (=sum of warping distances) is as follows.

$${( 4 , 4 )}^{th} element : 1 = \vert 10 - 9 \vert + min ( 6 , 11 , 0 ) = 1 + 0$$

$${( 2 , 1 )}^{th} element : 0 = \vert 1 - 1 \vert + min ( 0 ) = 0$$

$${( 1 , 3 )}^{th} element : 12 = \vert 1 - 10 \vert + min ( 3 ) = 12$$

If necessary, the warping path cost may be used as quantitative data for determining the similarity between the two data.

In the present invention, in the mapping between the representative sample data RD and the general sample data ND, data points constituting the minimum cost path may be mapped to each other, such as the path shaded in FIG. 7 described above.

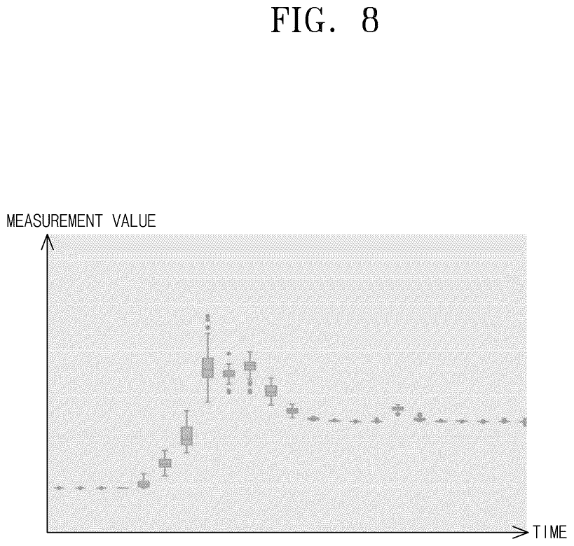

FIG. 8 is a graph for describing a method for deriving reference data including a reference band by applying an IQR to each data point.

Referring to FIGS. 2 and 8, in operation S3, a distribution of measurement values for each data point is calculated. Since the general sample data ND is mapped based on the data point of the representative sample data RD in operation S2 described above, distribution of measurement values of the representative sample data RD and the general sample data ND may be confirmed for each of the data points of the representative sample data RD as illustrated in FIG. 8.

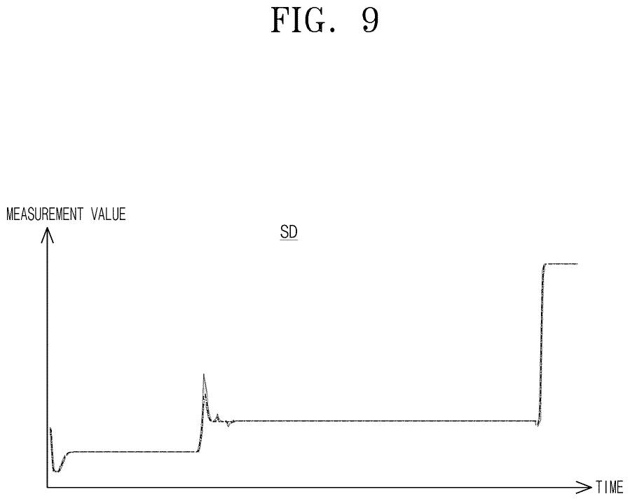

Thereafter, in operation S4, reference data SD may be derived by removing data which is equal to or greater than a maximum setting value and equal to or less than a minimum setting value from the distribution of each data point. The maximum setting value may be a value of upper 25% and the minimum setting value may be a value of lower 25%. That is, in operation S4, a range of stable normal measurement values for each data point is derived by applying an Inter Quartile Range (IQR) to each data point. A range of normal measurement values for each data point may be referred to as a reference band, and each reference band may function as a threshold range used when determining whether the determination target data TD is abnormal. The reference data SD includes a reference band for each data point. The derived reference data SD may be as illustrated in FIG. 9.

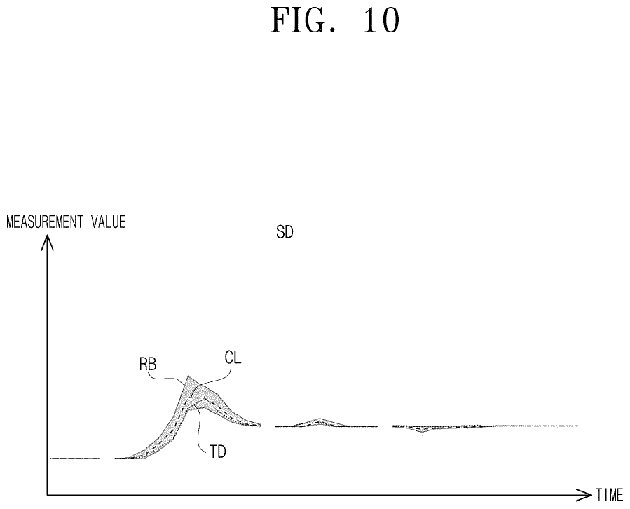

FIG. 10 is a graph for describing a method of determining whether a process at the time of collecting determination target data is an abnormal process by applying the reference data of FIG. 9.

Referring to FIGS. 2 and 10, in operation S5, it is determined whether the substrate processing process when the determination target data TD is collected is a normal process or an abnormal process by comparing the determination target data TD and the reference data SD.

The size of a first reference band at a first data point included in the reference data SD may be different from a size of a second reference band at a second data point. The present invention derives a reference band for each data point included in the reference data SD. This is because the distribution range of normal measurement values, which may be different for each process step, is reflected. Therefore, the reference data SD may be data with very high precision in determining a process abnormality.

It is very difficult for the general statistical method to derive a threshold range for each data point. For example, when data points exist at intervals of 300 ms, it is difficult to check a measurement value for each data point, and when multiple sample data SDN are used, it is unclear which data points should be used as the basis for calculating statistical measures of the measurement values. In contrast, in the present invention, by applying the mapping methodology of the DTW algorithm, measurement values of general sample data ND are collected based on the representative sample data RD, and a reference band is derived for each data point based on the measurement values, so process abnormality detection using the reference data SD may be performed with a high level of precision.

The derived reference data SD may be previously stored in the controller 20 of the substrate processing apparatus 1. In addition, the substrate processing apparatus 1 collects the determination target data TD while processing a substrate. The determination target data TD may be collected by the sensors 30. The measurement values of the sensors 30 may be transmitted to the controller 20 in real time. The controller 20 may record a measurement value of the sensor 30 for each data point while one substrate is processed.

In determining whether there is a process abnormality, an intermediate value CL may be derived for each data point, and how far the target data TD deviates from the corresponding intermediate line CL is digitized, which may be used to determine the degree of process abnormality. For example, when it is assumed that the distance between the upper limit and the intermediate value CL or between the lower limit and the intermediate value CL of each reference band is 1, it may be managed in a manner that when the distance between the determination target data TD and the intermediate value CL is 1 or less, the process is determined as a normal process, and when the distance between the determination target data TD and the intermediate value CL is greater than 1, the process is determined as an abnormal process. Alternatively, it may be managed in a manner that when the distance between the determination target data TD and the intermediate value CL is greater than 1 and is equal to or less than 2, the warning is generated, and when the distance between the determination target data TD and the intermediate value CL is greater than 2, the process is determined as an abnormal process.

Meanwhile, as described above, the plurality of sensors 30 may be provided. Accordingly, the above-described reference data SD may be derived as a number corresponding to the number of sensors 30. For example, when the first sensor 31 is a temperature sensor and the second sensor 32 is a pressure sensor, first reference data that is reference data SD about temperature and second reference data that is reference data SD about pressure may be derived. Likewise, the determination target data may be composed of first determination target data collected by the first sensor 31 and second determination target data that is collected by the second sensor 32. The controller 20 may compare the first reference data and the first determination target data, and compare the second reference data and the second determination target data with each other. The first and second determination target data may be data collected while processing one substrate. The controller 20 may detect whether there is an abnormality in the process when the first and second determination target data are collected based on the comparison result.

In addition, in this case, the weight of the first and second reference data may be different when detecting whether there is a process abnormality. For example, a first process abnormality score in which the degree of process abnormality is digitized based on the distance between the intermediate value of the first reference data and the first determination target data as described above, and a second process abnormality score in which the degree of process abnormality is digitized based on the distance between the intermediate value of the second reference data and the second determination target data are derived. In addition, the first process abnormality score and the second process abnormality score are multiplied by the weight, in consideration of the importance of the sensor 30 according to the type of process. For example, when the plasma process is performed in the process chamber 10, the current/voltage distribution in the chamber or the like may be a factor that has a greater influence on the overall process than the pressure in the chamber. In this case, the process abnormality score corresponding to the voltage and current sensors may be multiplied by a larger weight, and the other process abnormality scores may be multiplied by lower weights.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even if not specifically illustrated or described. The modifications are not to be considered as departing from the spirit and scope of the present invention, and all such modifications that would be obvious to one of ordinary skill in the art are intended to be included within the scope of the accompanying claims.

What is claimed is:

1. A method of detecting a process abnormality, the method comprising:
deriving reference data from a plurality of sample data, and comparing the derived reference data with determination target data to detect an abnormality in a process performed while the determination target data is collected,
wherein the sample data and the determination target data are data collected while a process of processing a substrate is performed,
the reference data includes:
a first reference band, which is a threshold range at a first data point; and
a second reference band, which is a threshold range at a second data point, in which the second data point is a point having a measurement value acquisition time point different from the first data point, and
the first reference band and the second reference band have different sizes.

2. The method of claim 1, wherein the deriving of the reference data includes:
selecting sample data having the longest data length among the plurality of sample data as representative sample data, and
mapping the selected representative sample data and each of general sample data excluding the representative sample data among the plurality of sample data.

3. The method of claim 2, wherein in the deriving of the reference data, when the representative sample data and each of the general sample data are mapped, a cost table of the representative sample data and the general sample data is calculated by applying a dynamic time warping algorithm, and the mapping is performed based on data points that serve as a minimum cost path in the cost table, and
the mapping is performed based on the data points of the representative sample data.

4. The method of claim 3, wherein in the deriving of the reference data, after performing the mapping, a distribution of the measurement values is calculated for each of the data points.

5. The method of claim 4, wherein in the deriving of the reference data, the reference data is derived by removing data having a value equal to or greater than a maximum setting value and equal to or less than to a minimum setting value from the distribution of each of the data points.

6. The method of claim 4, wherein in the process of processing the substrate, different types of sensors each collect the sample data and the determination target data,
first reference data, which is the reference data, is derived from the sample data collected by a first sensor,
second reference data, which is the reference data, is derived from the sample data collected by a second sensor of a different type from the first sensor, and
based on a result of comparing first determination target data, which is the determination target data, collected by the first sensor with the first reference data, and a result of comparing second determination target data, which is the determination target data, collected by the second sensor with the second reference data, it is determined whether the process of processing the substrate is abnormal.

7. A non-transitory computer-readable recording medium storing a program comprising instructions which, when executed by a processor, cause the processor to perform the method of detecting the process abnormality of claim 1.

8. An apparatus for processing a substrate, the apparatus comprising:
a process chamber for performing a process of processing the substrate;
at least one sensor for collecting a measurement value for a process factor related to the process; and
a controller for receiving the measurement value measured by the sensor,
wherein the controller controls the process chamber to perform the process of processing the substrate multiple times to collect a plurality of sample data from the sensor, and
derives reference data from the plurality of sample data and stores the derived reference data in a recording medium of the controller,
the reference data includes:
a first reference band, which is a threshold range at a first data point; and
a second reference band, which is a threshold range at a second data point, in which the second data point is a point having a measurement value acquisition time point different from the first data point, and
the first reference band and the second reference band have different sizes.

9. The apparatus of claim 8, wherein in the deriving of the reference data, the controller selects sample data having the longest data length among the plurality of sample data as representative sample data, and
maps the selected representative sample data and each of general sample data excluding the representative sample data among the plurality of sample data.

10. The apparatus of claim 9, wherein in the deriving of the reference data,
when the representative sample data and each of the general sample data are mapped, the controller calculates a cost table of the representative sample data and the general sample data by applying a dynamic time warping algorithm, and performs the mapping based on data points that serve as a minimum cost path in the cost table, and
the mapping is performed based on the data points of the representative sample data.

11. The apparatus of claim 10, wherein in the deriving of the reference data, the controller calculates a distribution of the measurement values for each of the data points, after performing the mapping.

12. The apparatus of claim 11, wherein in the deriving of the reference data, the controller derives the reference data by removing data having a value equal to or greater than a maximum setting value and equal to or less than to a minimum setting value from the distribution of each of the data points.

13. The apparatus of claim 8, further comprising:
a plurality of different types of the sensors,
wherein each of the sensors collects the sample data and determination target data that requires determination of whether a process abnormality has occurred and transmits the measurement value to the controller, and
the controller derives first reference data, which is the reference data, from the sample data collected by a first sensor among the sensors,
derives second reference data, which is the reference data, from the sample data collected by a second sensor of a different type from the first sensor among the sensors, and
determines whether the process of processing the substrate is abnormal based on a result of comparing first determination target data, which is the determination target data, collected by the first sensor with the first reference data, and a result of comparing second determination target data, which is the determination target data, collected by the second sensor with the second reference data.
